(19) United States
(12) Patent Application Publication
(10) Pub. No.: US 2025/0096522 A1
(43) Pub. Date: Mar. 20, 2025

(54) OPTOELECTRONIC DEVICE AND MANUFACTURING METHOD THEREOF

(71) Applicant: AuthenX Inc., Hsinchu County (TW)

(72) Inventors: Sheng-Fu LIN, Hsinchu County (TW); Po-Kuan SHEN, Hsinchu County (TW); Yi-Ting LU, Hsinchu County (TW); Chu-Ching TSAI, Hsinchu County (TW); Jenq-Yang CHANG, Hsinchu County (TW); Mao-Jen WU, Hsinchu County (TW)

(73) Assignee: AuthenX Inc., Hsinchu County (TW)

(21) Appl. No.: 18/889,471

(22) Filed: Sep. 19, 2024

Related U.S. Application Data
(60) Provisional application No. 63/583,965, filed on Sep. 20, 2023.

(51) Int. Cl. H01S 5/02326; H01S 5/00; H01S 5/026

(52) U.S. Cl. CPC H01S 5/02326; H01S 5/0071; H01S 5/026

(57) ABSTRACT

An optoelectronic device includes a first substrate, a second substrate, a photonic integrated circuit, and a laser diode. The second substrate is over the first substrate. The photonic integrated circuit is disposed on the first substrate and includes a first waveguide channel, a second waveguide channel, and a patterned structure. The first waveguide channel and the second waveguide channel are coupled to the patterned structure. The laser diode is disposed on the second substrate and configured to emit a light beam toward the patterned structure.

### CROSS-REFERENCE TO RELATED APPLICATION

This application claims priority to U.S. Provisional Application Ser. No. 63/583,965, filed Sep. 20, 2023, which is herein incorporated by reference in its entirety.

### BACKGROUND

### Field of Disclosure

The present disclosure relates to an optoelectronic device and a manufacturing method thereof.

### Description of Related Art

As process technology advances, requirements for data transmission and calculation rates increase. Therefore, the semiconductor industry is facing the challenge of integrating more complex circuits into unit area. However, the data transmission bandwidth of traditional electronic integrated circuits (EIC) is limited. As a result, how to integrate optical components into electronic integrated circuits has become a critical issue to be solved by those in the industry, to convert electrical signals into optical signals for data transmission to increase data transmission bandwidth.

### SUMMARY

An aspect of the disclosure is to provide an optoelectronic device and a manufacturing method of an optoelectronic device that may efficiently solve the aforementioned problems.

According to an embodiment of the disclosure, an optoelectronic device includes a first substrate, a second substrate, a photonic integrated circuit, and a laser diode. The second substrate is over the first substrate. The photonic integrated circuit is disposed on the first substrate and includes a first waveguide channel, a second waveguide channel, and a patterned structure. The first waveguide channel and the second waveguide channel are coupled to the patterned structure. The laser diode is disposed on the second substrate and configured to emit a light beam toward the patterned structure.

In an embodiment of the disclosure, a first axis of the first waveguide channel and a second axis of the second waveguide channel extend and intersect in the patterned structure.

In an embodiment of the disclosure, an included angle between the first axis of the first waveguide channel and the second axis of the second waveguide channel is between about 80 degrees and about 100 degrees.

In an embodiment of the disclosure, the laser diode is disposed over the patterned structure so that the light beam emitted by the laser diode is incident perpendicularly to the first substrate.

In an embodiment of the disclosure, the patterned structure includes a plurality of island-shaped units in a central area of the patterned structure, and a first axis of the first waveguide channel and a second axis of the second waveguide channel extend and intersect in the central area.

In an embodiment of the disclosure, a shortest diameter of any one of the island-shaped units or a pitch between any two adjacent ones of the island-shaped units is less than an operation wavelength of the light beam.

In an embodiment of the disclosure, the patterned structure further includes a multipronged unit between the central area and the first waveguide channel. The multipronged unit has a backbone and a prong connected to the backbone. The backbone is adjacent to the first waveguide channel. The prong is adjacent to the central area.

In an embodiment of the disclosure, the patterned structure includes a plurality of linear units in a diagonal area of the patterned structure. The diagonal area is at a side of the patterned structure that is away from the first waveguide channel. Each of the linear units has a normal vector substantially parallel to a first axis of the first waveguide channel.

In an embodiment of the disclosure, a shortest diameter of any one of the linear units or a pitch between any two adjacent ones of the linear units is less than an operation wavelength of the light beam.

In an embodiment of the disclosure, a gap between a light-emitting window of the laser diode and the patterned structure is between about 500 nm and about 100 μm.

In an embodiment of the disclosure, any side length of an outer edge of the patterned structure is between about 0.8 times and about 5 times a diameter of a light-emitting window of the laser diode.

According to another embodiment of the disclosure, a manufacturing method of an optoelectronic device includes providing a first substrate. The first substrate includes a photonic integrated circuit thereon. The photonic integrated circuit includes a first waveguide channel, a second waveguide channel, and a patterned structure. The first waveguide channel and the second waveguide channel are coupled to the patterned structure. The manufacturing method further includes providing a second substrate including a laser diode. The manufacturing method further includes docking the first substrate and the second substrate so that a light-emitting window of the laser diode faces the patterned structure of the photonic integrated circuit.

In an embodiment of the disclosure, docking the first substrate and the second substrate so that the laser diode is disposed over the patterned structure of the photonic integrated circuit. The laser diode is configured to emit a light beam perpendicularly to the first substrate.

In an embodiment of the disclosure, the patterned structure of the photonic integrated circuit includes a plurality of island-shaped units in a central area of the patterned structure. A shortest diameter of any one of the island-shaped units or a pitch between any two adjacent ones of the island-shaped units is less than an operation wavelength of the light beam emitted by the laser diode.

In an embodiment of the disclosure, a first axis of the first waveguide channel and a second axis of the second waveguide channel extend and intersect in the central area.

In an embodiment of the disclosure, an included angle between the first axis of the first waveguide channel and the second axis of the second waveguide channel is between about 80 degrees and about 100 degrees.

In an embodiment of the disclosure, the island-shaped units are configured to scatter the light beam in a plurality of different directions.

In an embodiment of the disclosure, the patterned structure further includes a multipronged unit between the central area and the first waveguide channel. The multipronged unit has a backbone and a prong connected to the backbone. The multipronged unit is configured to receive the light beam passing through the prong and partially guide the light beam to the backbone so that the light beam is shaped and coupled to the first waveguide channel.

In an embodiment of the disclosure, the patterned structure includes a plurality of linear units in a diagonal area of the patterned structure. The diagonal area is at a side of the patterned structure that is away from the first waveguide channel. A shortest diameter of any one of the linear units or a pitch between any two adjacent ones of the linear units is less than an operation wavelength of a light beam emitted by the laser diode.

In an embodiment of the disclosure, each of the linear units has a normal vector substantially parallel to a first axis of the first waveguide channel to block the light beam incident to the linear units and partially reflect the light beam to the first waveguide channel.

Accordingly, in the optoelectronic device and the manufacturing method of the optoelectronic device of the present disclosure, the substrate provided with the photonic integrated circuit is docked with the substrate provided with the laser diode. The photonic integrated circuit includes two waveguide channels and a patterned structure that promotes light coupling to the two waveguide channels. Therefore, higher optical coupling efficiency that is polarization independent may be achieved. To be more specific, the included angle between the two waveguide channels is deliberately selected so that the light beams coupled to the two waveguide channels are substantially equal in quantity. In addition, the patterned structure is a sub-wavelength structure and includes units with different shapes and characteristic lengths. Thus, the sub-wavelength structure may match the mode of the incident laser light more effectively, while reducing energy loss and maintaining a more stable optical coupling efficiency in a wider wavelength range.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a perspective view of an optoelectronic device according to some embodiments of the present disclosure;

FIG. 1B is a partial enlarged view of FIG. 1A;

FIG. 2 is a side view of an optoelectronic device taken along a line A-A′ of FIG. 1A according to some embodiments of the present disclosure;

FIG. 3 is a cross-sectional view of a second substrate of an optoelectronic device taken along a line B-B′ of FIG. 1A according to some embodiments of the present disclosure;

FIG. 4A and FIG. 4B are top views of a first waveguide channel, a second waveguide channel, and a patterned structure of an optoelectronic device according to some embodiments of the present disclosure; and

FIG. 5 is a graph of optical coupling efficiency versus polarization angle of an optoelectronic device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

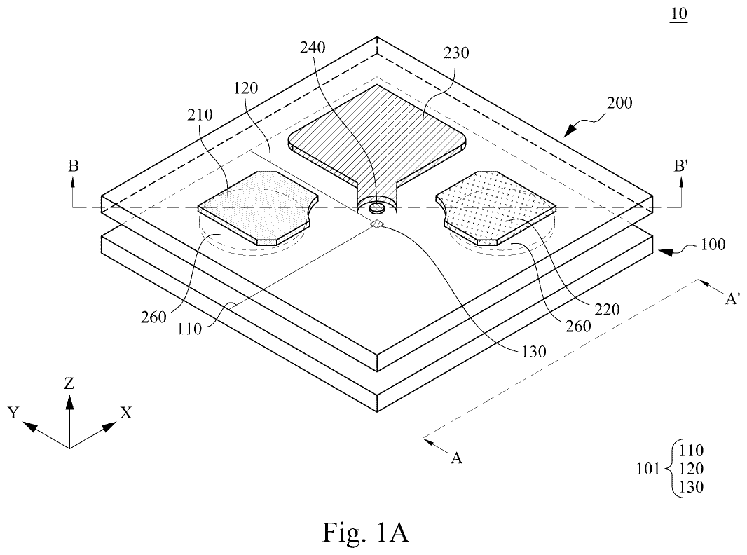

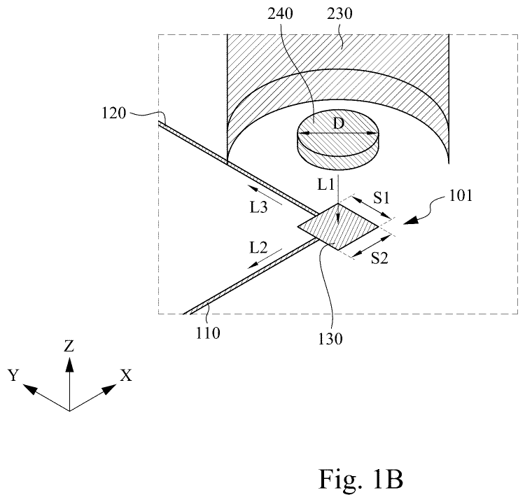

Reference is made to FIG. 1A. FIG. 1A is a perspective view of an optoelectronic device 10 according to some embodiments of the present disclosure. The optoelectronic device 10 includes a first substrate 100 and a second substrate 200 docked with each other. As shown in FIG. 1A, the second substrate 200 may be disposed over the first substrate 100. A photonic integrated circuit 101 is disposed on a surface of the first substrate 100 facing the second substrate 200. A laser diode is disposed on a surface of the second substrate 200 facing the first substrate 100. The laser diode is configured to emit a light beam toward the patterned structure 130. It should be understood that in order to show the relative positions between the components, the concrete structure of the laser diode is omitted in FIG. 1A, and only a light-emitting window 240 of the laser diode is shown for illustration. The structure of the laser diode will be described in detail with other figures in following paragraphs.

The photonic integrated circuit 101 on the first substrate 100 may include a first waveguide channel 110, a second waveguide channel 120, and a patterned structure 130, as shown in FIG. 1A. The first waveguide channel 110 extends in a direction X. The second waveguide channel 120 extends in a direction Y. Each of the first waveguide channel 110 and the second waveguide channel 120 has one end coupled to the patterned structure 130. The other ends of the first waveguide channel 110 and the second waveguide channel 120 may be coupled to other optical elements, such as optical fibers, respectively, but this disclosure is not limited thereto. The patterned structure 130 includes microstructures with different geometric and optical properties. Detailed features of the patterned structure 130 will be described in following paragraphs.

As shown in FIG. 1A, the optoelectronic device 10 further includes a pad 210, a pad 220, and a pad 230 disposed on the surface of the second substrate 200 facing the first substrate 100. In some embodiments, the pad 220 and the pad 230 are electrically connected to the laser diode. In some embodiments, the pad 230 serves as an anode of the laser diode, and the pad 220 serves as a cathode of the laser diode to provide electrical signals to drive the laser diode. In some embodiments, the pad 210 may be in a floating state and serves as a spacer together with the pad 220 and the pad 230 to maintain the gap between the first substrate 100 and the second substrate 200. Thereby, the distance of the light-emitting window 240 relative to the patterned structure 130 may be adjusted. In some embodiments, the pad 210 may be made of a different material than the pad 220 and the pad 230.

Reference is made to FIG. 1B. FIG. 1B is an enlarged partial view of FIG. 1A. As shown in FIG. 1B, the light-emitting window 240 is disposed directly over the patterned structure 130. For example, a central axis of the light-emitting window 240 may be substantially aligned with a center of the patterned structure 130. The light-emitting window 240 has a diameter D. The laser diode emits a light beam L1 toward the patterned structure 130 through the light-emitting window 240. The light beam L1 is diverted and scattered by the microstructures of the patterned structure 130 to form a light beam L2 and a light beam L3 coupled to the first waveguide channel 110 and the second waveguide channel 120, respectively. In some embodiments, an overall outer edge of the patterned structure 130 is approximately quadrangular, as shown in FIG. 1B. Any side length of the outer edge of the quadrangular (such as a side length S1 and a side length S2) is between about 0.8 times and about 5 times the diameter D of the light-emitting window 240 of the laser diode.

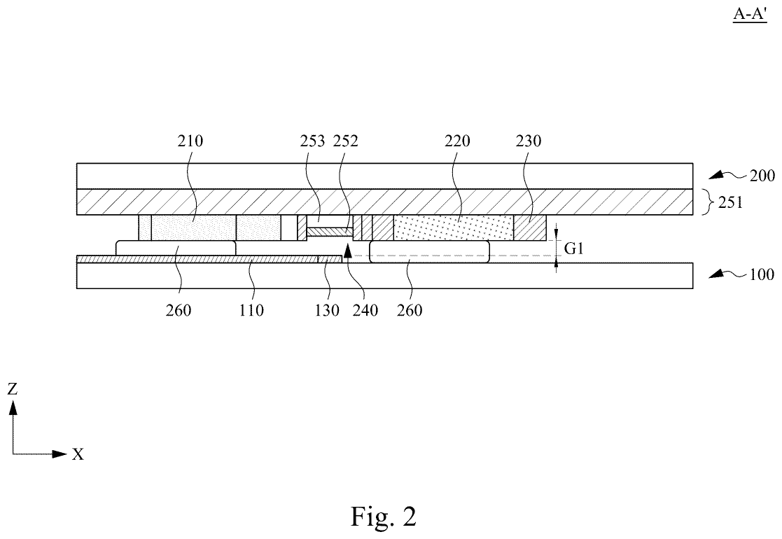

Reference is made to FIG. 2. FIG. 2 is a side view of the optoelectronic device 10 taken along a line A-A′ shown in FIG. 1A according to some embodiments of the present disclosure. As shown in FIG. 2, the pad 210, the pad 220, and the pad 230 are disposed between the first substrate 100 and the second substrate 200 to separate the first substrate 100 and the second substrate 200. In some embodiments, the pad 210, the pad 220, and the pad 230 disposed on the second substrate 200 may be respectively connected to pads of the first substrate 100 through solder bumps 260. For example, a thickness of the solder bumps 260 is deliberately selected such that a gap G1 between the light-emitting window 240 and the patterned structure 130 along a direction Z is between about 500 nm and about 100 μm. In some embodiments, the optoelectronic device 10 may further include a dielectric layer (not shown) disposed between the first substrate 100 and the second substrate 200 and covering each pad to protect the connection.

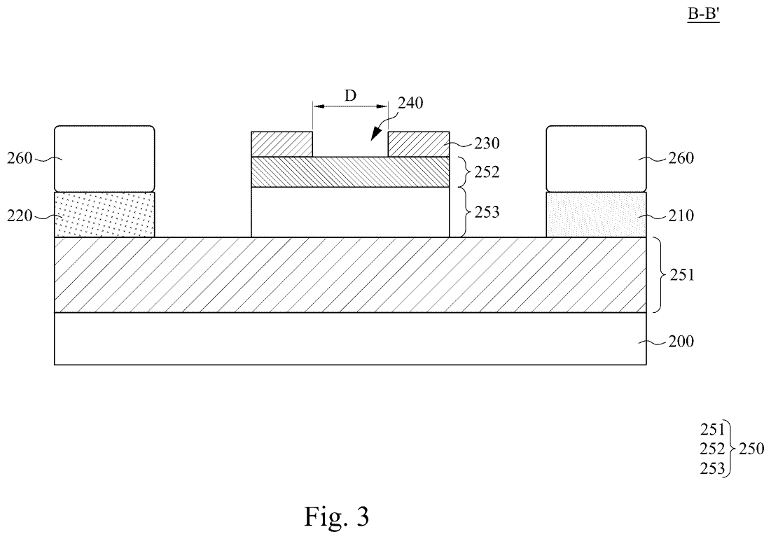

Reference is made to FIG. 3. FIG. 3 is a partial cross-sectional view of the second substrate 200 of the optoelectronic device 10 taken along a line B-B′ of FIG. 1A according to some embodiments of the present disclosure. As aforementioned, the laser diode 250 is disposed on the surface of the second substrate 200 facing the first substrate 100. For the sake of clarity, in FIG. 3, the second substrate 200 is shown in the bottom part of the figure, and the light-emitting window 240 of the laser diode 250 is positioned upward. In some embodiments, as shown in FIG. 3, the laser diode 250 may be a laser element such as a vertical cavity surface emitting laser (VCSEL) or a laser element that guides a light beam toward the first substrate 100 so that the light beam has the shown light transmission mode through secondary optical structures. The laser diode 250 includes a first reflective layer 251, a second reflective layer 252, and a light-emitting layer 253 disposed between the first reflective layer 251 and the second reflective layer 252. In some embodiments, each of the first reflective layer 251 and the second reflective layer 252 has a plurality of stacked compound semiconductor material layers to form different types of distributed Bragg reflectors (DBR). The first reflective layer 251 is coupled to the pad 220 used as the cathode, and the second reflective layer 252 is coupled to the pad 230 used as the anode. In some embodiments, the light-emitting layer 253 is a multiple quantum well (MQW) structure. In some embodiments, the first reflective layer 251, the second reflective layer 252, and the light-emitting layer 253 may include a same material and may be doped with different doping species or doping concentrations so that they have different electrical properties. In addition, as shown in FIG. 3, the pad 230 may surround and define the light-emitting window 240. The light-emitting window 240 has a diameter D. It should be noted that the pad 210, the pad 220, and the pad 230 shown in FIG. 3 may be portions extended from the pad 210, the pad 220, and the pad 230 shown in FIG. 1A and FIG. 2. Therefore, the pad 210, the pad 220, and the pad 230 shown in FIG. 3 may have different relative positional relationships than the pad 210, the pad 220, and the pad 230 shown in FIG. 1A and FIG. 2. For example, a height of a top surface of the pad 230 may be greater than heights of top surfaces of the pad 220 and the pad 230 shown in FIG. 3. In some other embodiments, the laser diode 250 may be a laser element formed based on prior arts and configured to emit a light beam perpendicularly to the first substrate 100, but the present disclosure is not limited thereto.

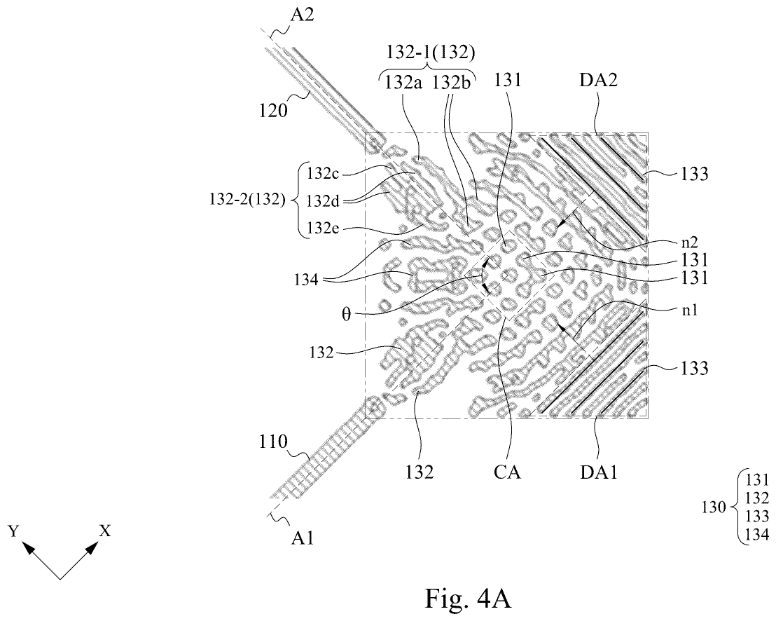

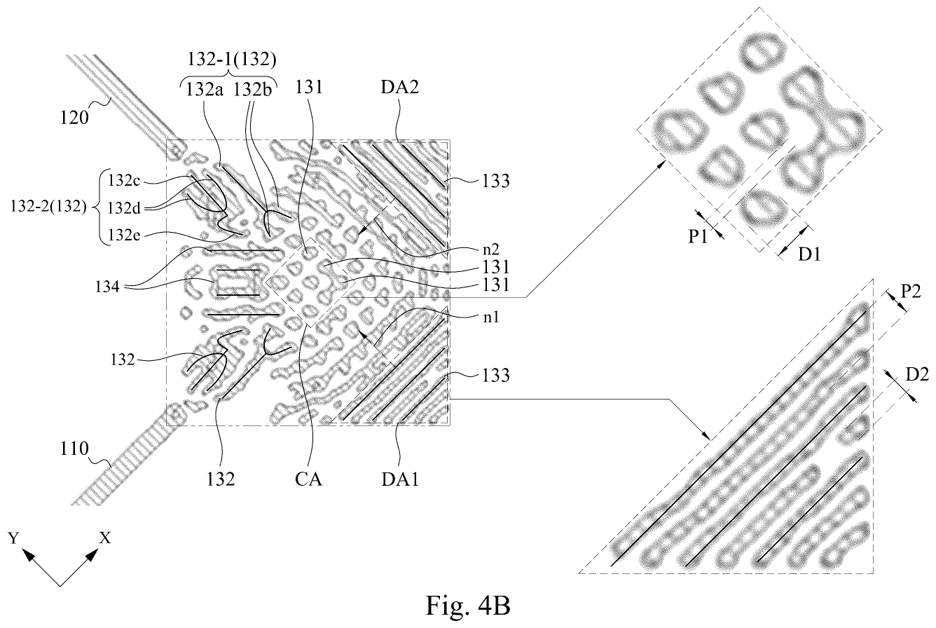

Reference is made to FIG. 4A and FIG. 4B. FIG. 4A and FIG. 4B are top views of the first waveguide channel 110, the second waveguide channel 120, and the patterned structure 130 according to some embodiments of the present disclosure. The first waveguide channel 110, the second waveguide channel 120, and the patterned structure 130 shown in FIG. 4A and FIG. 4B are the same, but for the sake of clarity, different auxiliary lines are drawn for explanation.

As aforementioned, the patterned structure 130 has an outer edge that is approximately quadrangular. As shown in FIG. 4A, the first waveguide channel 110 and the second waveguide channel 120 extend into the quadrangular outer edge of the patterned structure 130 and are coupled to the patterned structure 130.

In greater detail, the patterned structure 130 has a central area CA, a diagonal area DA1, and a diagonal area DA2. The central area CA is disposed at the center of the quadrangular outer edge of the patterned structure 130. The diagonal area DA1 and the diagonal area DA2 are disposed at two opposite corners of the outer edge of the quadrangular. The diagonal area DA1 is disposed at a side of the patterned structure 130 that is away from the second waveguide channel 120. The diagonal area DA2 is disposed at a side of the patterned structure 130 that is away from the first waveguide channel 110. As shown in FIG. 4A, the diagonal area DA1 and the diagonal area DA2 are substantially symmetrical. A first axis A1 of the first waveguide channel 110 and a second axis A2 of the second waveguide channel 120 extend and intersect in the central area CA of the patterned structure 130 and form an included angle θ. In some embodiments, the included angle θ is between about 80 degrees and about 100 degrees. For example, the included angle θ may be substantially 90 degrees. In such case, the light beams coupled to the first waveguide channel 110 and the second waveguide channel 120 are substantially equal in quantity. In addition, the first axis A1 of the first waveguide channel 110 extends toward the diagonal area DA2, and the second axis A2 of the second waveguide channel 120 extends toward the diagonal area DA1.

Reference is made to FIG. 4B. The patterned structure 130 includes units with different shapes and characteristic lengths, such as island-shaped units 131, multipronged units 132, linear units 133, and partition units 134. These units are disposed in different areas of the patterned structure 130 and have different light-guiding properties. In some embodiments, these units can be obtained by inverse design according to desired optical coupling characteristics of the optoelectronic device 10.

Furthermore, in some embodiments, a shortest diameter of any pattern of these units or the pitch between any two adjacent units is less than an operation wavelength of the light beam emitted by the laser diode. Taking this embodiment as an example, if the operation wavelength of the light beam is about 1300 nm, the shortest diameter of any pattern of the units or the pitch between any two adjacent units can be designed to be less than about half of the operation wavelength, such as less than about 650 nm. However, this disclosure is not limited to this. The shortest diameter of any pattern of the units or the pitch between any two adjacent units may also be between about 150 nm and about 300 nm as needed. To be more specific, the patterned structure 130 is a sub-wavelength structure. The sub-wavelength structure may match the mode of the incident laser light more effectively and reduce reflection and scattering, thereby reducing energy loss during the optical coupling process. In addition, the sub-wavelength structure may maintain higher optical coupling efficiency over a wider wavelength range. This is important for multi-wavelength or broad-spectrum applications to ensure stable performance across a wide range of wavelengths. For example, a 1 dB bandwidth of the patterned structure 130 formed according to FIG. 4B exceeds about 20 nm.

To be more specific, as shown in FIG. 4B, the patterned structure 130 includes the island-shaped units 131 in the central area CA. The island-shaped units 131 have approximately circular contours. In other words, characteristic lengths of the island-shaped unit 131 in the direction X and the direction Y are similar. In some embodiments, the arrangement of the island-shaped units 131 may be periodic, semi-periodic, or non-periodic. In addition, as aforementioned, in the central area CA, the shortest diameter D1 of the patterns of the island-shaped units 131 or the pitch P1 between two adjacent island-shaped units 131 is less than the operation wavelength of the light beam.

As shown in FIG. 4B, the patterned structure 130 includes multipronged units 132 between the central area CA and the waveguide channel (i.e., the first waveguide channel 110 or the second waveguide channel 120). Each of the multipronged units 132 has a backbone and at least one prong connected to the backbone. One end of the backbone faces the waveguide channel, and the other end of the backbone faces the central area CA. A direction of the prongs intersects with a direction of the backbone. For example, a multipronged unit 132-1 has a backbone 132a and two prongs 132b connected to the backbone. One end of the backbone 132a faces the second waveguide channel 120, and the other end faces the central area CA. The two prongs 132b are adjacent to the central area CA and their directions intersect with the direction of the backbone 132a, forming a Y-shaped unit. On the other hand, a multipronged unit 132-2 has a backbone 132c, two prongs 132d connected to the backbone and adjacent to the second waveguide channel 120, and a prong 132e connected to the backbone and adjacent to the central area CA. Similarly, directions of the two prongs 132d and the prong 132e intersect with the direction of the backbone 132c.

As shown in FIG. 4B, the patterned structure 130 includes the linear units 133 in the diagonal area DA1 and the diagonal area DA2. The linear units 133 have approximately elongated contours. In other words, characteristic lengths of the linear units 133 in the direction X are significantly different from characteristic lengths of the linear units 133 in the direction Y. For example, the characteristic lengths of the linear units 133 in the diagonal area DA1 in the direction X is at least twice the characteristic lengths in the direction Y. In addition, reference is made to FIG. 4A and FIG. 4B. Each of the linear units 133 in the diagonal area DA1 has a normal vector n1 that is substantially parallel to the second axis A2 of the second waveguide channel 120, and each of the linear units 133 in the diagonal area DA2 has a normal vector n2 that is substantially parallel to the first axis A1 of the first waveguide channel 110. In some embodiments, an included angle between the normal vector n1 and the normal vector n2 is between about 80 degrees and about 100 degrees. Moreover, as aforementioned, the shortest diameter D2 of the patterns of the linear units 133 in the diagonal area DA1 and the diagonal area DA2 or the pitch P2 between two adjacent linear units 133 is less than the operation wavelength of the light beam.

As shown in FIG. 4B, the patterned structure 130 includes the partition units 134 between the first waveguide channel 110 and the second waveguide channel 120 and between the two waveguide channels and the central area CA. In some embodiments, an included angle between a direction of the partition units 134 and the first axis A1 of the first waveguide channel 110 as well as an included angle between the direction of the partition units 134 and the second axis A2 of the second waveguide channel 120 are between about 40 degrees and about 50 degrees, respectively.

In some embodiments, as shown in FIG. 4B, a transition zone exists between two adjacent areas of the patterned structure 130. The characteristics of the units in one area gradually change over the transition zone into the characteristics of the units in another adjacent area. Therefore, the units in the transition zone can have some of the light-guiding properties of the units in both areas. For example, the units between the central area CA and the diagonal area DA1 in FIG. 4B have irregular contours combining the approximately circular contours of the island-shaped units 131 and the approximately elongated contours of the linear units 133, such as approximately jagged contours. These units have the function of scattering incident light while blocking and reflecting the incident light.

By arranging the units with different shapes and characteristic lengths to scatter, block, or guide the light beam, the patterned structure 130 may improve the coupling efficiency of the light beam into the two waveguide channels. In greater detail, since the light-emitting window 240 is disposed directly over the patterned structure 130, the light beam will first be received by the central area CA after emitted by the laser diode. Then, the island-shaped units 131 in the central area CA are configured to divert and scatter the light beam in different directions. For example, the light beam is split into different light portions scattered along a positive direction of the direction Y, a negative direction of the direction X, a negative direction of the direction Y, and a positive direction of the direction X. After a first light portion is diverted by the island-shaped units 131, the first light portion propagates toward the second waveguide channel 120 along the positive direction of the direction Y. Then, the multipronged unit 132-1 and the multipronged unit 132-2 receive the first light portion through the prongs adjacent to the central area CA, guide the first light portion to the backbones and the prongs adjacent to the first waveguide channel 110, thereby performing beam shaping. The shaped first light portion is coupled to the second waveguide channel 120. Similarly, a second light portion is coupled to the first waveguide channel 110 along the negative direction of the direction X. On the other hand, after a third light portion is diverted by the island-shaped units 131, the third light portion propagates toward the diagonal area DA1 along the negative direction of the direction Y. Then, the linear units 133 in the diagonal area DA1 block the third light portion to prevent light leakage. Since the normal vector n1 of the linear units 133 in the diagonal area DA1 is substantially parallel to the second axis A2 of the second waveguide channel 120, the third light portion may be partially reflected and pass through the central area CA again toward the second waveguide channel 120. Also, the third light portion is shaped and coupled to the second waveguide channel 120 through the multipronged units 132. Similarly, the fourth light portion propagates along the positive direction of the direction X. Then, the fourth light portion is blocked and partially reflected by the linear units 133 in the diagonal area DA2, shaped through the multipronged units 132, and coupled to the first waveguide channel 110. During the process of light transmission and coupling, the partition units 134 are configured to prevent the light portions guided to the first waveguide channel 110 and the light portions guided to the second waveguide channel 120 from interfering with each other.

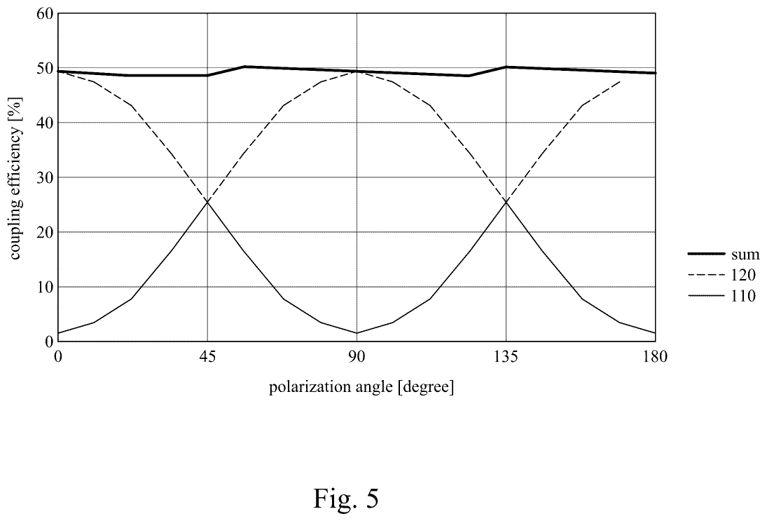

Reference is made to FIG. 5. FIG. 5 is a graph of optical coupling efficiency versus polarization angle of the optoelectronic device 10 according to some embodiments of the present disclosure. As shown in FIG. 5, the thin solid line represents the optical coupling efficiency of the first waveguide channel 110. The dotted line represents the optical coupling efficiency of the second waveguide channel 120. The thick solid line represents the sum of the optical coupling efficiencies of the two waveguide channels. It can be seen that in an embodiment where the included angle θ between the first axis A1 and the second axis A2 is substantially 90 degrees, the sum of the optical coupling efficiencies of the first waveguide channel 110 and the second waveguide channel 120 can reach similar values when the light beams have different polarization angles. Therefore, the optoelectronic device 10 according to some embodiments of the present disclosure can achieve higher overall optical coupling efficiency that is polarization independent.

The following paragraphs describe the manufacturing method of the optoelectronic device according to some embodiments of the present disclosure.

First, a first substrate is provided. As aforementioned, a photonic integrated circuit is disposed on a surface of the first substrate. The photonic integrated circuit includes a first waveguide channel, a second waveguide channel, and a patterned structure. In some embodiments, the first waveguide channel, the second waveguide channel, and the patterned structure are formed through an etching process. The first waveguide channel and the second waveguide channel are coupled to the patterned structure. In some embodiments, a first axis of the first waveguide channel and a second axis of the second waveguide channel extend and intersect in the patterned structure. In some embodiments, an included angle between the first axis of the first waveguide channel and the second axis of the second waveguide channel is between about 80 degrees and about 100 degrees. In some embodiments, the patterned structure has microstructures as previously described. In some embodiments, the patterned structure is a sub-wavelength structure.

Next, a second substrate is provided. The second substrate is provided with a laser diode and pads electrically connected to the laser diode. In some embodiments, the laser diode may be a vertical cavity surface emitting laser (VCSEL). In some other embodiments, the laser diode may be a laser element formed using prior arts. The present disclosure is not limited thereto.

Then, the first substrate and the second substrate are docked together so that the light-emitting window of the laser diode faces the patterned structure of the photonic integrated circuit, thereby forming the optoelectronic device 10 of the present disclosure. In some embodiments, docking the first substrate with the second substrate includes flipping the second substrate or the first substrate so that the surface of the first substrate provided with the photonic integrated circuit faces the surface of the second substrate where the light-emitting window is disposed. In some embodiments, docking the first substrate with the second substrate such that the laser diode is disposed directly over the patterned structure of the photonic integrated circuit. For example, a central axis of the light-emitting window of the laser diode may be substantially aligned to a center of the patterned structure with tolerances within 1 μm. The laser diode is configured to emit a light beam perpendicularly to the first substrate. The patterned structure is configured to couple the light beam emitted by the laser diode to the first waveguide channel and the second waveguide channel.

Accordingly, in the optoelectronic device and the manufacturing method of the optoelectronic device of the present disclosure, the substrate provided with the photonic integrated circuit is docked with the substrate provided with the laser diode. The photonic integrated circuit includes two waveguide channels and a patterned structure that promotes light coupling to the two waveguide channels. Therefore, higher optical coupling efficiency that is polarization independent may be achieved. To be more specific, the included angle between the two waveguide channels is deliberately selected so that the light beams coupled to the two waveguide channels are substantially equal in quantity. In addition, the patterned structure is a sub-wavelength structure and includes units with different shapes and characteristic lengths. Thus, the sub-wavelength structure may match the mode of the incident laser light more effectively, while reducing energy loss and maintaining a more stable optical coupling efficiency in a wider wavelength range.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. An optoelectronic device, comprising:
a first substrate;
a second substrate over the first substrate;
a photonic integrated circuit disposed on the first substrate and comprising a first waveguide channel, a second waveguide channel, and a patterned structure, wherein the first waveguide channel and the second waveguide channel are coupled to the patterned structure; and
a laser diode disposed on the second substrate and configured to emit a light beam toward the patterned structure.

2. The optoelectronic device of claim 1, wherein a first axis of the first waveguide channel and a second axis of the second waveguide channel extend and intersect in the patterned structure.

3. The optoelectronic device of claim 2, wherein an included angle between the first axis of the first waveguide channel and the second axis of the second waveguide channel is between about 80 degrees and about 100 degrees.

4. The optoelectronic device of claim 1, wherein the laser diode is disposed over the patterned structure so that the light beam emitted by the laser diode is incident perpendicularly to the first substrate.

5. The optoelectronic device of claim 1, wherein the patterned structure comprises a plurality of island-shaped units in a central area of the patterned structure, and a first axis of the first waveguide channel and a second axis of the second waveguide channel extend and intersect in the central area.

6. The optoelectronic device of claim 5, wherein a shortest diameter of any one of the island-shaped units or a pitch between any two adjacent ones of the island-shaped units is less than an operation wavelength of the light beam.

7. The optoelectronic device of claim 5, wherein the patterned structure further comprises a multipronged unit between the central area and the first waveguide channel, wherein the multipronged unit has a backbone and a prong connected to the backbone, the backbone is adjacent to the first waveguide channel, and the prong is adjacent to the central area.

8. The optoelectronic device of claim 1, wherein the patterned structure comprises a plurality of linear units in a diagonal area of the patterned structure, wherein the diagonal area is at a side of the patterned structure that is away from the first waveguide channel, and each of the linear units has a normal vector substantially parallel to a first axis of the first waveguide channel.

9. The optoelectronic device of claim 8, wherein a shortest diameter of any one of the linear units or a pitch between any two adjacent ones of the linear units is less than an operation wavelength of the light beam.

10. The optoelectronic device of claim 1, wherein a gap between a light-emitting window of the laser diode and the patterned structure is between about 500 nm and about 100 μm.

11. The optoelectronic device of claim 1, wherein any side length of an outer edge of the patterned structure is between about 0.8 times and about 5 times a diameter of a light-emitting window of the laser diode.

12. A manufacturing method of an optoelectronic device, comprising:
providing a first substrate comprising a photonic integrated circuit thereon, wherein the photonic integrated circuit comprises a first waveguide channel, a second waveguide channel, and a patterned structure, and the first waveguide channel and the second waveguide channel are coupled to the patterned structure;
providing a second substrate comprising a laser diode; and
docking the first substrate and the second substrate so that a light-emitting window of the laser diode faces the patterned structure of the photonic integrated circuit.

13. The manufacturing method of claim 12, wherein docking the first substrate and the second substrate so that the laser diode is over the patterned structure of the photonic integrated circuit, and the laser diode is configured to emit a light beam perpendicularly to the first substrate.

14. The manufacturing method of claim 12, wherein the patterned structure of the photonic integrated circuit comprises a plurality of island-shaped units in a central area of the patterned structure, and a shortest diameter of any one of the island-shaped units or a pitch between any two adjacent ones of the island-shaped units is less than an operation wavelength of a light beam emitted by the laser diode.

15. The manufacturing method of claim 14, wherein a first axis of the first waveguide channel and a second axis of the second waveguide channel extend and intersect in the central area.

16. The manufacturing method of claim 15, wherein an included angle between the first axis of the first waveguide channel and the second axis of the second waveguide channel is between about 80 degrees and about 100 degrees.

17. The manufacturing method of claim 14, wherein the island-shaped units are configured to scatter the light beam in a plurality of different directions.

18. The manufacturing method of claim 14, wherein the patterned structure further comprises a multipronged unit between the central area and the first waveguide channel, the multipronged unit has a backbone and a prong connected to the backbone, and the multipronged unit is configured to receive the light beam passing through the prong and partially guide the light beam to the backbone, so that the light beam is shaped and coupled to the first waveguide channel.

19. The manufacturing method of claim 12, wherein the patterned structure comprises a plurality of linear units in a diagonal area of the patterned structure, wherein the diagonal area is at a side of the patterned structure that is away from the first waveguide channel, and a shortest diameter of any one of the linear units or a pitch between any two adjacent ones of the linear units is less than an operation wavelength of a light beam emitted by the laser diode.

20. The manufacturing method of claim 19, wherein each of the linear units has a normal vector substantially parallel to a first axis of the first waveguide channel to block the light beam that is incident to the linear units and partially reflect the light beam to the first waveguide channel.
